(19) United States
(12) Patent Application Publication
(10) Pub. No.: US 2004/0051444 A1
(43) Pub. Date: Mar. 18, 2004

(54) Articles having raised features and methods for making the same

(75) Inventors: Marc Schaepkens, Ballston Lake, NY (US); Joseph John Shiang, Niskayuna, NY (US); Anil Raj Duggal, Niskayuna, NY (US); Christian Maria Anton Heller, Albany, NY (US); Donald Franklin Foust, Glenville, NY (US)

Correspondence Address: GENERAL ELECTRIC COMPANY, GLOBAL RESEARCH CENTER, PATENT DOCKET RM. 4A59, PO BOX 8, BLDG. K-1 ROSS, NISKAYUNA, NY, 12309, US

(73) Assignee: General Electric Company, Niskayuna, NY (US)

(21) Appl. No.: 10/065,093

(22) Filed: Sep. 17, 2002

(51) Int. Cl. H05B 33/00; H05B 33/14

(52) U.S. Cl. 313/504

(57) ABSTRACT

An article has a plurality of raised features on at least one of its surfaces. The raised features have a form of ridges or islands. The article is made by conducting a material through the space between two solid surfaces, at least one of which has a negative image of the pattern of the raised features. Such an article serves as a substrate upon which a matrix of individually addressable light-emitting devices are formed.

### BACKGROUND OF INVENTION

The present invention relates generally to articles having raised features on a surface and methods for making such articles. In particular, the present invention relates to substrates comprising a polymeric material and having a pattern of raised features on at least one surface thereof, methods for making, and organic electroluminescent formed on such substrates.

Electroluminescent (“EL”) devices, which may be classified as either organic or inorganic, are well known in graphic display and imaging art. EL devices have been produced in different shapes for many applications. Inorganic EL devices, however, typically suffer from a required high activation voltage and low brightness. On the other hand, organic EL devices (“OELDs”), which have been developed more recently, offer the benefits of lower activation voltage and higher brightness in addition to simple manufacture, and, thus, the promise of more widespread applications.

An OELD is typically a thin film structure formed on a substrate such as glass or transparent plastic. A light-emitting layer of an organic EL material and optional adjacent semiconductor layers are sandwiched between a cathode and an anode. The semiconductor layers may be either hole (positive charge)-injecting or electron (negative charge)-injecting layers and also comprise organic materials. The material for the light-emitting layer may be selected from many organic EL materials. The light emitting organic layer may itself consist of multiple sublayers, each comprising a different organic EL material. State-of-the-art organic EL materials can emit electromagnetic (“EM”) radiation having narrow ranges of wavelengths in the visible spectrum. Unless specifically stated, the terms “EM radiation” and “light” are used interchangeably in this disclosure to mean generally radiation having wavelengths in the range from ultraviolet (“UV”) to mid-infrared (“mid-IR”) or, in other words, wavelengths in the range from about 300 nm to about 10 micrometer. To achieve white light, prior-art devices incorporate closely arranged OELDs emitting blue, green, and red light. These colors are mixed to produce white light. In one configuration described in U.S. Pat. Nos. 5,294,869 and 5,294,870 and published U.S. Patent Application US 2002/0011785 A1, these OELDs are formed as adjacent pixels that are individually addressable. Separated areas of one or more organic EL materials and color conversion layers coupled thereto are deposited on a patterned electrode that provides the capability electrically to control the individual pixels. The deposition of these layers is effected by a shadow mask that comprises a plurality of walls that are first formed on the substrate by photolithography. The portions of the surface in the shadow of the walls do not receive vapor directed at an angle at such surface. Thus, the locations of the deposited areas are controlled by the heights of the walls and the angle of deposition. However, this process involves the additional step of forming the walls of the shadow mask from a negative-working photoresist composition by a tedious photolithography technique.

Therefore, it would be desirable to provide articles having a pattern of raised features that are easily and inexpensively produced and can be used for the construction of light-emitting devices. It would also be very desirable to provide matrix displays built on these patterned substrates.

### SUMMARY OF INVENTION

An article comprises a polymeric material and a plurality of raised features that are formed on a surface thereof.

In one aspect of the present invention, a method for making a polymeric article, at least a surface of which has a pattern of raised features, comprises conducting a polymeric material against a solid surface on which a negative image of the pattern is formed.

In another aspect of the present invention, a matrix display comprises a substrate and a plurality of light-emitting devices formed on at least an area of the substrate, which area is selected from the group consisting of the raised features, the surface between the raised features, and combinations thereof.

Other features and advantages of the present invention will be apparent from a perusal of the following detailed description of the invention and the accompanying drawings in which the same numerals refer to like elements.

### BRIEF DESCRIPTION OF DRAWINGS

FIG. 1 shows the elevation of the first embodiment of the invention.

FIG. 2 shows the elevation of the second embodiment of the invention.

FIG. 3 shows the elevation of the third embodiment of the invention.

FIG. 4 is the perspective of an article having raised rectangular ridges.

FIG. 5 is the perspective of an article having ridges of inverted truncated prisms.

FIG. 6 schematically shows an apparatus for continuously making a film having raised features.

FIG. 7 is the perspective of an article having raised islands.

FIG. 8 shows a plurality of OELDs formed on an article of FIG. 2.

FIG. 9 shows a plurality of OELDs formed on an article of FIG. 1.

FIG. 10 shows an alternate embodiment of a plurality of OELDs formed on an article of FIG. 1.

### DETAILED DESCRIPTION

The present invention provides a substrate, at least a surface of which has a pattern of raised features and methods for making such a substrate. The substrate and the raised features can comprise the same or different materials. Such a substrate provides a simple, convenient method of making matrix display devices.

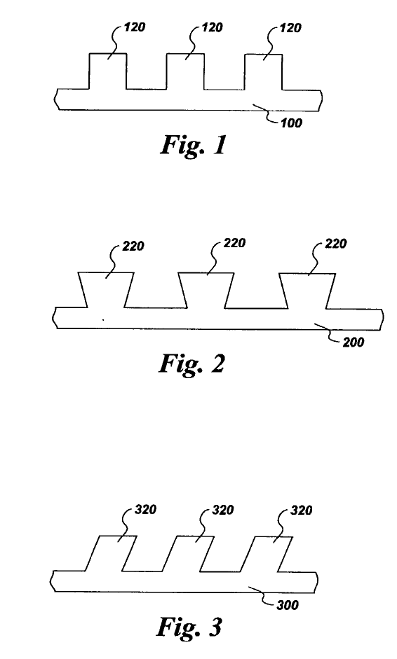

FIGS. 1, 2, and 3 show substrates 100, 200, or 300 having different forms of raised features 120, 220, or 320. It should be understood that the drawings accompanying the present disclosure are not drawn to scale.

Substrate 100, 200, or 300 comprises an organic polymeric material; such as such as polyethyleneterephthalate (“PET”); polyacrylates; polycarbonates; silicone; epoxy resins; silicone-functionalized epoxy resins; polyesters such as Mylar (made by E.I. du Pont de Nemours & Co.); polyimides such as Kapton H or Kapton E (made by du Pont), Apical AV (made by Kanegafugi Chemical Industry Company), Upilex (made by UBE Industries, Ltd.); polyethersulfones (“PES,” made by Sumitomo); polyetherimide such as Ultem (made by General Electric Company); and polyethylenenaphthalene (“PEN”). Raised features 110, 210, or 310 can be formed as a matrix of rows and column or as a series of long rows. The dimension of each raised feature and the distance between two adjacent raised features typically correspond to the desired dimension of a pixel of the matrix display. For high-density, high-resolution information displays, the pixel dimension can be in the range from about 5 micrometers to about 100 micrometers. On the other hand, for general lighting purposes, the pixel area can be up to several square centimeters. The height of the raised features is typically in the range from about 1 micrometer to about 100 micrometers.

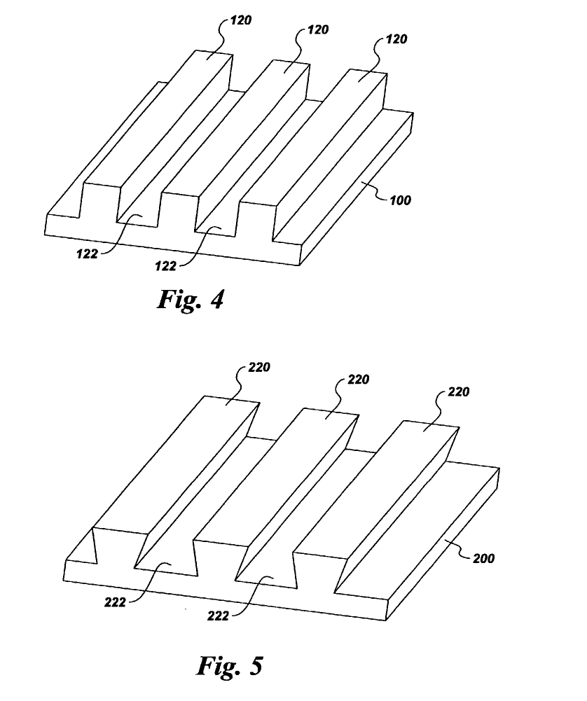

In one embodiment of the present invention, an article having a pattern of raised features is produced by conducting a material through a space between two plates. A plate surface facing the space has a negative image of the pattern. In other words, the plate surface has a pattern of depressions, each of which corresponds to a raised feature on the article. In this case, the article can be produced that has a plurality of raised ridges 120 or 220, as shown in FIGS. 4 and 5. The material may be a completely or partially polymerized material. When a partially polymerized material is used, it is completely polymerized after said conducting to prevent a deformation of the pattern. In one embodiment, the step of conducting the material through the space between two plates comprises extruding the material through said space. Extrusion of polymeric materials is typically carried out under a superatmospheric pressure, such as from about 105 kPa to about 15000 kPa.

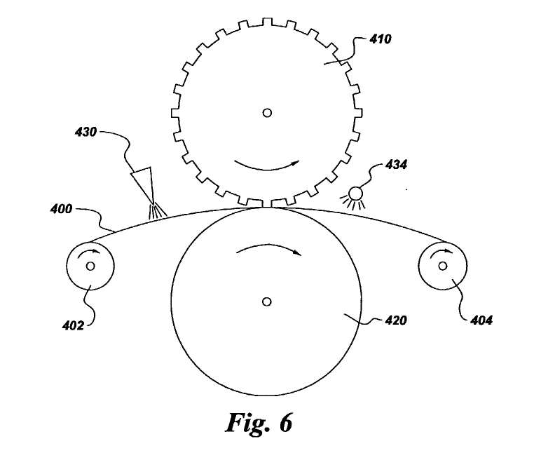

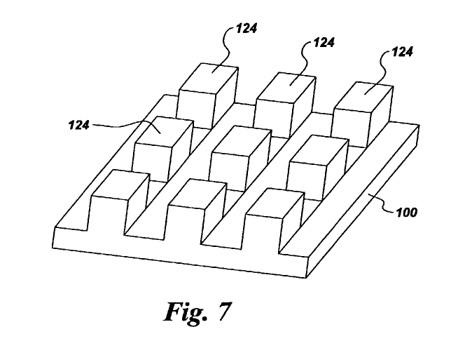

In another embodiment of the present invention as shown in FIG. 6 for a continuous manufacturing process, a film 400 of a polymeric material is passed between two cylindrical rollers 410 and 420. The surface of cylindrical roller 410 has the negative image of the pattern to be imparted on a surface of film 400. The polymeric film 400 is supplied from a supply roll 402 and taken up by a take-up roll 404, after passing through the gap between rollers 410 and 420. Suitable materials for film 400 are disclosed above. Nozzle 430 sprays an organic monomer or an unpolymerized material onto one surface of film 400 as it enters the gap between rollers 410 and 420. The term “unpolymerized material” means a material that has not polymerized or has only partially polymerized. As cylindrical rollers 410 and 420 press against film 400, a pattern of raised features is formed in the layer of organic monomer or unpolymerized material on film 400. The organic monomer or unpolymerized material is polymerized, for example using a curing or polymerization device 434 disposed adjacent to film 400 as it passes through the gap between rollers 410 and 420. The polymerization permanently fixes the pattern of raised features on film 400. Curing or polymerization device 434 can be a radiation source, a heat source, or a combination thereof, depending on the mechanism of the polymerization reaction. In one example, the monomer is an acrylate monomer, such as methyl methacrylate, ethyl acrylate, 2-hydroxyethyl acrylate, or hydroxypropyl acrylate, and the polymerization reaction is initiated by a UV radiation source and completed by a heat source. In another example, a mixture of monomers and a catalyst (such as a mixture of dimethyl terephthalate, ethylene glycol, and sodium methoxide) is sprayed onto film 400, and the polymerization is completed with a heat source. The aforementioned monomers may be substituted with other monomers. The choice of monomers and catalysts to produce particular polymers is within the skills of people in the art. This method of manufacturing can produce a substrate having a pattern of raised ridges 120, as shown in FIG. 4, or raised isolated islands 124, as shown in FIG. 7.

In another embodiment of the present invention, a substrate having raised features shown in FIG. 5 may be obtained from the substrate of FIG. 4 by ablating portions of the sides of ridges 120, for example with a laser.

Individual OELDs can be built on top of ridges 120 or 220 and/or in valleys 122 or 222 between ridges 120 or 220. The OELDs thus built can be addressed individually to display information or images represented by the collection of activated OELDs. Typically, an OELD comprises at least an organic electroluminescent (“EL”) layer capable of emitting light when activated by a voltage, which organic EL layer is sandwiched between two conductor layers serving as an anode and a cathode.

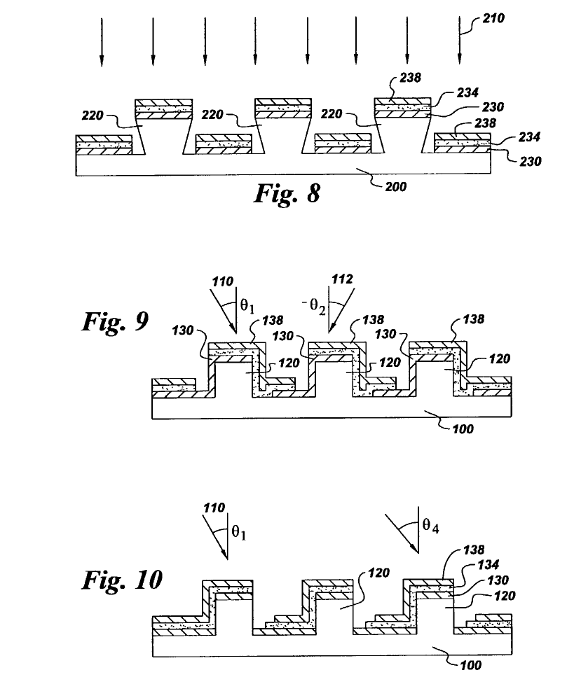

FIG. 8 shows schematically a display comprising a matrix of OELDs built on a substantially transparent plastic substrate 200 having raised features 220. As used herein, a material is substantially transparent when it allows a total transmission of at least 50 percent, preferably at least 80 percent, more preferably at least 90 percent, and most preferably at least 95 percent, of light in the visible range (i.e., having wavelengths in the range from about 400 nm to about 700 nm). Successive layers 230, 234, and 238 of an anode, an organic EL, and a cathode material are deposited on substrate 200 in the direction of arrow 210. Indium tin oxide (“ITO”) is typically used as the anode material, which should typically be a high work function in the range of about 4.5 eV to about 5.5 eV. ITO is substantially transparent to light transmission and allows at least 80% light transmitted therethrough. Therefore, light emitted from organic electroluminescent layer 234 can easily escape through the ITO anode layer without being seriously attenuated. Other materials suitable for use as the anode layer are tin oxide, indium oxide, zinc oxide, indium zinc oxide, cadmium tin oxide, and mixtures thereof. In addition, materials used for the anode may be doped with aluminum or fluorine to improve charge injection property. Electrode layers 230 and 238 may be deposited on the underlying element by physical vapor deposition, chemical vapor deposition, ion beam-assisted deposition, or sputtering. A thin, substantially transparent layer of a metal is also suitable.

Low-work function materials (those having work function less than about 4.5 eV) suitable for use as a cathode are K, Li, Na, Mg, La, Ce, Ca, Sr, Ba, Al, Ag, In, Sn, Zn, Zr, Sm, Eu, alloys thereof, or mixtures thereof. Preferred materials for the manufacture of cathode layer 238 are Ag—Mg, Al—Li, In—Mg, and Al—Ca alloys. Layered non-alloy structures are also possible, such as a thin layer of a metal such as Ca (thickness from about 1 to about 10 nm) or a non-metal such as LiF, covered by a thicker layer of some other metal, such as aluminum or silver.

When a voltage is applied across electrodes 230 and 238, positive charge carriers (or holes) and negative charge carriers (electrons) are injected from anode 230 and cathode 238, respectively, into organic EL layer 234 where they combine and drop to a lower energy level, concurrently emitting electromagnetic (“EM”) radiation in the visible range. Organic EL layer 234 can be deposited by physical vapor deposition or chemical vapor deposition. Organic EL materials are chosen to electroluminesce in the desired wavelength range. The thickness of the organic EL layer 330 is preferably kept in the range of about 100 to about 300 nm. The organic EL material may be a polymer, a copolymer, a mixture of polymers, or lower molecular-weight organic molecules having unsaturated bonds. Such materials possess a delocalized π-electron system, which gives the polymer chains or organic molecules the ability to support positive and negative charge carriers with high mobility. Suitable EL polymers are poly(N-vinylcarbazole) (“PVK”, emitting violet-to-blue light in the wavelengths of about 380-500 nm); poly(alkylfluorene) such as poly(9,9-dihexylfluorene) (410-550 nm), poly(dioctylfluorene) (wavelength at peak EL emission of 436 nm), or poly{9,9-bis(3,6-dioxaheptyl)-fluorene-2,7-diyl} (400-550 nm); poly(praraphenylene) derivatives such as poly(2-decyloxy-1,4-phenylene) (400-550 nm). Mixtures of these polymers or copolymers based on one or more of these polymers and others may be used to tune the color of emitted light.

Another class of suitable EL polymers is the polysilanes. Polysilanes are linear silicon-backbone polymers substituted with a variety of alkyl and/or aryl side groups. They are quasi one-dimensional materials with delocalized σ-conjugated electrons along polymer backbone chains. Examples of polysilanes are poly(di-n-butylsilane), poly(di-n-pentylsilane), poly(di-n-hexylsilane), poly(methylphenylsilane), and poly{bis(p-butylphenyl)silane} which are disclosed in H. Suzuki et al., “Near-Ultraviolet Electroluminescence From Polysilanes,” 331 Thin Solid Films 64-70 (1998). These polysilanes emit light having wavelengths in the range from about 320 nm to about 420 nm.

Organic materials having molecular weight less than about 5000 that are made of a large number of aromatic units are also applicable. An example of such materials is 1,3,5-tris{n-(4-diphenylaminophenyl) phenylamino}benzene, which emits light in the wavelength range of 380-500 nm. The organic EL layer also may be prepared from lower molecular weight organic molecules, such as phenylanthracene, tetraarylethene, coumarin, rubrene, tetraphenylbutadiene, anthracene, perylene, coronene, or their derivatives. These materials generally emit light having maximum wavelength of about 520 nm. Still other suitable materials are the low molecular-weight metal organic complexes such as aluminum-, gallium-, and indium-acetylacetonate, which emit light in the wavelength range of 415-457 nm, aluminum-(picolymethylketone)-bis{2,6-di(t-butyl)phenoxide} or scandium-(4-methoxy-picolylmethylketone)-bis (acetylacetonate), which emits in the range of 420-433 nm. For white light application, the preferred organic EL materials are those emit light in the blue-green wavelengths.

More than one organic EL layer may be formed successively one on top of another, each layer comprising a different organic EL material that emits in a different wavelength range. Such a construction can facilitate a tuning of the color of the light emitted from the overall light-emitting display device 299.

Furthermore, one or more additional layers may be included between electrodes 230 and 238 to increase the efficiency of the overall device 299. These additional layers are also deposited in the direction of arrow 210 by physical vapor deposition or chemical vapor deposition. For example, these additional layers can serve to improve the injection (electron or hole injection enhancement layers) or transport (electron or hole transport layers) of charges into the organic EL layer. The thickness of each of these layers is kept to below 500 nm, preferably below 100 nm. Materials for these additional layers are typically low-to-intermediate molecular weight (less than about 2000) organic molecules. In one embodiment of the present invention, a hole injection enhancement layer is formed between anode layer 230 and organic EL layer 234 to provide a higher injected current at a given forward bias and/or a higher maximum current before the failure of the device. Thus, the hole injection enhancement layer facilitates the injection of holes from the anode. Suitable materials for the hole injection enhancement layer are arylene-based compounds disclosed in U.S. Pat. No. 5,998,803; such as 3,4,9,10-perylenetetra-carboxylic dianhydride or bis(1,2,5-thiadiazolo)-p-quinobis(1,3-dithiole).

In another embodiment of the present invention, each OELD further includes a hole transport layer which is disposed between the hole injection enhancement layer and organic EL layer 234. The hole transport layer has the functions of transporting holes and blocking the transportation of electrons so that holes and electrons are optimally combined in organic EL layer 234. Materials suitable for the hole transport layer are triaryldiamine, tetraphenyldiamine, aromatic tertiary amines, hydrazone derivatives, carbazole derivatives, triazole derivatives, imidazole derivatives, oxadiazole derivatives having an amino group, and polythiophenes as disclosed in U.S. Pat. No. 6,023,371.

In still another embodiment of the present invention, each OELD includes an additional layer disposed between cathode layer 238 and organic EL layer 234. This additional layer has the combined function of injecting and transporting electrons to organic EL layer 234. Materials suitable for the electron injecting and transporting layer are metal organic complexes such as tris(8-quinolinolato)aluminum, oxadiazole derivatives, perylene derivatives, pyridine derivatives, pyrimidine derivatives, quinoline derivatives, quinoxaline derivatives, diphenylquinone derivatives, and nitro-substituted fluorene derivatives, as disclosed in U.S. Pat. No. 6,023,371.

In another aspect of the present invention, a mixture of an organic EL material and a dye is deposited between the electrodes of individual OELDs. The dye absorbs a portion of EM radiation emitted by the organic EL material and emits EM radiation in a different wavelength range. Different dyes are used for different OELDs to generate different colors. For example, dyes can be selected such that three adjacent OELDs emit blue, green, and red colors, which in combination result in white light.

Suitable classes of organic dyes are the perylenes and benzopyrenes, coumarin dyes, polymethine dyes, xanthene dyes, oxobenzanthracene dyes, perylenebis (dicarboximide) dyes, pyrans, thiopyrans, and azo dyes.

One or more inorganic photoluminescent (“PL” or phosphor) materials also can be mixed with the organic EL material to obtain color conversion. In this case, the mixture may be sprayed in the direction of arrow 210 on the raised features and in the valley areas between the raised features. An exemplary phosphor is the cerium-doped yttrium aluminum oxide Y₃Al₅O₁₂ garnet (“YAG:Ce”). Other suitable phosphors are based on YAG doped with more than one type of rare earth ions, such as (Y_{1-x-y}GdₓCe_{y})₃Al₅O₁₂(“YAG:Gd,Ce”), (Y₁₋ₓCeₓ)₃(Al_{1-y}Ga_{y})O₁₂(“YAG:Ga,Ce”), (Y_{1-x-y}GdₓCe_{y})(Al_{5-z}Ga_{z})O₁₂(“YAG:Gd,Ga,Ce”), and (Gd₁₋ₓCeₓ)Sc₂ Al₃O₁₂(“GSAG”) where 0≦x≦1, 0≦y≦1, 0≦z≦5 and x+y≦1. For example, the YAG:Gd,Ce phosphor shows an absorption of light in the wavelength range from about 390 nm to about 530 nm (i.e., the blue-green spectral region) and an emission of light in the wavelength range from about 490 nm to about 700 nm (i.e., the green-to-red spectral region). Related phosphors include Lu₃Al₅O₁₂ and Tb₂Al₅O₁₂, both doped with cerium. In addition, these cerium-doped garnet phosphors may also be additionally doped with small amounts of Pr (such as about 0.1-2 mole percent) to produce an additional enhancement of red emission. The following are examples of phosphors that are efficiently excited by EM radiation emitted in the wavelength region of 300 nm to about 500 nm by polysilanes and their derivatives.

Green-emitting phosphors: Ca₈Mg(SiO₄)₄Cl₂: Eu²⁺,Mn²⁺; GdBO₃: Ce³⁺, Tb³⁺; CeMgAl₁₁O₁₉: Tb³⁺; Y₂SiO₅: Ce³⁺, Tb³⁺; and BaMg₂Al₁₆O₂₇ : Eu²⁺,Mn²⁺.

Red-emitting phosphors: Y₂O₃: Bi³⁺,Eu³⁺; Sr₂P₂O₇: Eu²⁺,Mn²⁺; SrMgP₂O₇: Eu²⁺,Mn²⁺; (Y,Gd)(V,B)O₄: Eu³⁺; and 3.5 MgO.0.5 MgF₂.GeO₂: Mn⁴⁺(magnesium fluorogermanate).

Blue-emitting phosphors: BaMg₂Al₁₆O₂₇: Eu²⁺; Sr₅(PO₄)₁₀Cl₂: Eu²⁺; and (Ba,Ca,Sr)_{≡}(PO_{∝})₁₀(Cl,F)₂: Eu²⁺, (Ca,Ba,Sr)(Al,Ga)₂S₄ : Eu²⁺.

Yellow-emitting phosphors: (Ba,Ca,Sr)_{≡}(PO_{∝})₁₀(Cl,F)₂: Eu²⁺,Mn²⁺.

Still other ions may be incorporated into the phosphor to transfer energy from the light emitted from the organic material to other activator ions in the phosphor host lattice as a way to increase the energy utilization. For example, when Sb³⁺ and Mn²⁺ ions exist in the same phosphor lattice, Sb³⁺ efficiently absorbs light in the blue region, which is not absorbed very efficiently by Mn²⁺, and transfers the energy to Mn²⁺ ion. Thus, a larger total amount of light emitted by the organic EL material is absorbed by both ions, resulting in higher quantum efficiency of the total device.

In another embodiment of the present invention as shown in FIG. 9, a matrix display is built on substrate 100, which has raised features or islands 120. Substrate 100 is made of a substantially transparent polymeric material, such as one of the polymers disclosed above. A substantially transparent conductor material, such as ITO, is sputter-deposited on the raised features and in the valleys therebetween in the direction of arrow 110, which makes an angle θ₁ with the normal to the surface of substrate 100. This deposition step results in an anode layer 130 being deposited at isolated areas of the substrate. In particular, the areas in the shadow of raised features 120 do not receive the anode material. Next, an organic EL material (or a mixture of an organic EL material and a PL material) is deposited in the direction of arrow 112 at an angle θ₂ with respect to the normal to the surface of substrate 100 to form an EL layer 134. Then a cathode material is deposited thereon at angle θ₃, in general, with respect to the normal to the surface of substrate 100. In the embodiment shown in FIG. 9, θ₂ is substantially equal to θ₃. The absolute values of angles θ₁,−θ₂, and −θ₃ may be substantially the same if desired. This process produces a plurality of OELDs that are individually addressable. Alternatively, combinations of other deposition directions including a normal to the surface of substrate 100 can be used to form OLEDs having different layers at desired locations. For example, FIG. 10 shows an array of OELDs formed by depositing anode layer 134 in the direction of the normal to the surface, and organic EL layer 134 and cathode layer 138 at angles θ₁ and θ₄, respectively. It should be understood that in the most general case, the deposition angles (θ₁, θ₂, θ₃, θ₄, etc.) are different. A power supply is supplied to the light-emitting elements or OELDs of FIGS. 8, 9, and 10 to activate them. A power supply lead can be connected to each of the anodes of the light-emitting elements or OELDs or the anodes of a group of the OELDs can be connected together and to a common power supply lead. Similarly, a second power lead can be connected to each of the OELDs or a group of OELDs connected together to complete an electrical circuit.

While specific preferred embodiments of the present invention have been disclosed in the foregoing, it will be appreciated by those skilled in the art that many modifications, substitutions, or variations may be made thereto without departing from the spirit and scope of the invention as defined in the appended claims.

1. An article comprising a polymeric material and a plurality of raised features formed on a surface thereof, said raised features comprising said polymeric material.

2. The article according to claim 1, wherein said raised features have a shape selected from the group consisting of ridges and islands.

3. The article according to claim 1, wherein a cross-sectional area of a raised feature decreases as a distance from said surface decreases.

4. The article according to claim 1, wherein said polymeric material comprises a material selected from the group consisting of polyethyleneterephthalate, polyacrylates, polycarbonates, silicone, epoxy resins, silicone-functionalized epoxy resins, polyesters, polyimides, polyethersulfones, polyetherimide, polyethylenenaphthalene, and mixtures thereof.

5. The article according to claim 1, wherein said raised features has a dimension in a range from about 5 micrometers to about 100 micrometers.

6. The article according to claim 1, wherein said raised features has a height in a range from about 1 micrometer to about 100 micrometers.

7. An article comprising a polymeric material and a plurality of raised features formed on a surface thereof; wherein said raised features comprising said polymeric material; said polymeric material comprises a material selected from the group consisting of polyethyleneterephthalate, polyacrylates, polycarbonates, silicone, epoxy resins, silicone-functionalized epoxy resins, polyesters, polyimides, polyethersulfones, polyetherimide, polyethylenenaphthalene, and mixtures thereof; said raised features have a shape selected from the group consisting of ridges and islands and have a dimension in a range from about 5 micrometers to about 100 micrometers.

8. A method for making an article having a pattern of raised features on at least a surface thereof, said method comprising conducting a material through a space between two solid surfaces, at least one of said solid surfaces having a negative image of said pattern.

9. The method according to claim 8, wherein said conducting comprises extruding through said space.

10. The method according to claim 8, wherein said material is conducting through a gap between two counter-rotating cylindrical rollers and surfaces of said rollers comprise said two solid surfaces.

11. The method according to claim 8, further comprising ablating a portion of each of said raised features near said surface.

12. A method for making an article having a pattern of raised features on at least a surface thereof, said method comprising the steps of:
providing a polymeric film on a supply roll;
conducting said polymeric film through a space between two solid surfaces, at least one of said solid surfaces having a negative image of said pattern, thereby forming said pattern of said raised features on said film; and
winding said film having said raised features on a take-up roll.

13. The method according to claim 12, further comprising the steps of:
depositing an unpolymerized material on a surface said film before conducting said film having said unpolymerized material thereon through said space, said deposited unpolymerized material facing said surface having said negative image; and polymerizing substantially completely said unpolymerized material.

14. The method according to claim 13, wherein said polymerizing is carried out by a method selected from the group consisting of irradiating, heating, catalyzing, and combinations thereof.

15. The method according to claim 13, wherein said unpolymerized material comprises at least a monomer.

16. The method according to claim 15, wherein said monomer is an ultraviolet radiation-curable acrylate monomer.

17. The method according to claim 15, wherein said monomer is selected from the group consisting of methyl methacrylate, ethyl acrylate, 2-hydroxyethyl acrylate, hydroxypropyl acrylate, and mixture thereof, and said polymemizing is carried out by irradiating with an ultraviolet light source.

18. The method according to claim 13, wherein said unpolymerized material comprises at least a monomer and a polymerization initiator.

19. The method according to claim 18, wherein said unpolymerized material comprises dimethyl terephthalate and ethylene glycol and said polymerization initiator is sodium methoxide.

20. A light-emitting device comprising:
a substrate having a plurality of raised features on a surface thereof; and
a plurality of light-emitting elements, each of which is disposed on one of said raised features.

21. The light-emitting device according to claim 20, wherein said substrate comprises a substantially transparent polymeric material.

22. The light emitting device according to claim 20, wherein each of said light-emitting elements comprises a layer of an organic electroluminescent material sandwiched between two electrically conducting layers.

23. The light emitting device according to claim 20, wherein said organic electroluminescent material is capable of emitting light having a first wavelength range when a voltage is applied across said electrically conducting layers.

24. The light emitting device according to claim 20, wherein each of said light-emitting elements further comprises a layer of a photoluminescent material that is capable of absorbing a portion of light emitting by said organic electroluminescent material and emitting light having a different wavelength range.
